(19) United States
(12) Patent Application Publication
(10) Pub. No.: US 2010/0009527 A1
(43) Pub. Date: Jan. 14, 2010

(54) INTEGRATED CIRCUIT SYSTEM EMPLOYING SINGLE MASK LAYER TECHNIQUE FOR WELL FORMATION

(75) Inventors: Yong Meng Lee, Singapore (SG); Chung Woh Lai, Singapore (SG); Huang Liu, Singapore (SG); Wenzhi Gao, Singapore (SG); Zhao Lun, Singapore (SG); Johnny Widodo, Singapore (SG); Shailendra Mishra, Singapore (SG); Liang-Choo Hsia, Singapore (SG)

Correspondence Address: LAW OFFICES OF MIKIO ISHIMARU, 333 W. EL CAMINO REAL, SUITE 330, SUNNYVALE, CA, 94087, US

(73) Assignee: CHARTERED SEMICONDUCTOR MANUFACTURING LTD., Singapore (SG)

(21) Appl. No.: 12/172,724

(22) Filed: Jul. 14, 2008

(51) Int. Cl. H01L 21/266

(52) U.S. Cl. 438/527; 257/E21.346

(57) ABSTRACT

A method for manufacturing an integrated circuit system that includes: providing a substrate; forming a mask layer over the substrate; implanting a first well through an opening in the mask layer into the substrate; and implanting a second well through the mask layer and the opening via a single implant into the substrate.

### TECHNICAL FIELD

The present invention relates generally to integrated circuits, and more particularly to an integrated circuit system employing single mask layer techniques for well formation.

### BACKGROUND ART

Integrated circuits find application in many of today's consumer electronics, such as cell phones, video cameras, portable music players, printers, computers, etc. Integrated circuits may include a combination of active devices, passive devices and their interconnections.

Active devices, such as a metal-oxide-semiconductor field-effect transistor (MOSFET), generally include a semiconductor substrate, having a source, a drain, and a channel located between the source and drain. A gate stack composed of a conductive material (i.e., a gate) and an oxide layer (i.e., a gate oxide) are typically located directly above the channel. During operation, an inversion layer forms a conducting bridge or “channel” between the source and drain when a voltage is applied to the gate. Both p-channel and n-channel MOSFET technologies are available and can be combined on a single substrate in one technology, called complementary-metal-oxide-semiconductor or CMOS.

CMOS fabrication technology generally employs a “twin tub” process to form discrete, p-type well regions into which an NFET will be formed, and discrete, n-type well regions into which a PFET will be formed. Typically, the n-well regions and the p-well regions are defined by performing two separate masking steps. Such a process generally includes cleaning, depositing a first mask, patterning, implanting, stripping, cleaning, depositing a second mask, patterning, implanting and stripping. Unfortunately, such a process generally introduces mask overlay error between the first mask and the second mask that can result in an area of weakness between the wells due to overlapping and counter-doping, which can give rise to poor n+/n-well isolation and poor p+/p-well isolation.

Moreover, as lithography of integrated circuit devices is considered to be a bottleneck for throughput purposes (e.g., some estimate that lithography consumes up to sixty percent of the wafer's fabrication time), the additional masking steps of a “twin tub” process can lead to increased cost and complexity.

Thus, a need still remains for a reliable integrated circuit system and method of fabrication, wherein the integrated circuit system includes an n-well and a p-well formed by a single mask. In view of the ever-increasing commercial competitive pressures, increasing consumer expectations, and diminishing opportunities for meaningful product differentiation in the marketplace, it is increasingly critical that answers be found to these problems. Moreover, the ever-increasing need to save costs, improve efficiencies, and meet such competitive pressures adds even greater urgency to the critical necessity that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a method for manufacturing an integrated circuit system including: providing a substrate; forming a mask layer over the substrate; implanting a first well through an opening in the mask layer into the substrate; and implanting a second well through the mask layer and the opening via a single implant into the substrate.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a partial cross-sectional view of an integrated circuit system 100 in an initial stage of manufacture in accordance with an embodiment of the present invention;

FIG. 2 is the structure of FIG. 1 after forming a mask layer;

FIG. 3 is the structure of FIG. 2 during a second dopant implant;

FIG. 4 is the structure of FIG. 3 after removing a mask layer;

FIG. 5 is a flow chart of an integrated circuit system for an integrated circuit system in accordance with an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the system are semi-diagrammatic and not to scale and, particularly, some of the dimensions are for the clarity of presentation and are shown exaggerated in the drawing FIGs. Additionally, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

The term “processing” as used herein includes deposition of material or photoresist, patterning, exposure, development, etching, cleaning, and/or removal of the material or photoresist as required in forming a described structure.

The term “on” is used herein to mean there is direct contact among elements.

The terms “example” or “exemplary” are used herein to mean serving as an instance or illustration. Any aspect or embodiment described herein as an “example” or as “exemplary” is not necessarily to be construed as preferred or advantageous over other aspects or designs.

The terms “first” and “second” as used herein are for purposes of differentiation between elements only and are not to be construed as limiting the scope of the present invention.

The term “layer” encompasses both the singular and the plural unless otherwise indicated.

The term “system” as used herein means and refers to the method and to the apparatus of the present invention in accordance with the context in which the term is used.

Generally, the following embodiments relate to the formation of a first well region formed adjacent a second well region via a single mask. By forming a first well and a second well via the single mask process described herein, manufacturing operations can be simplified, costs can be reduced, and mask overlay error can be eliminated.

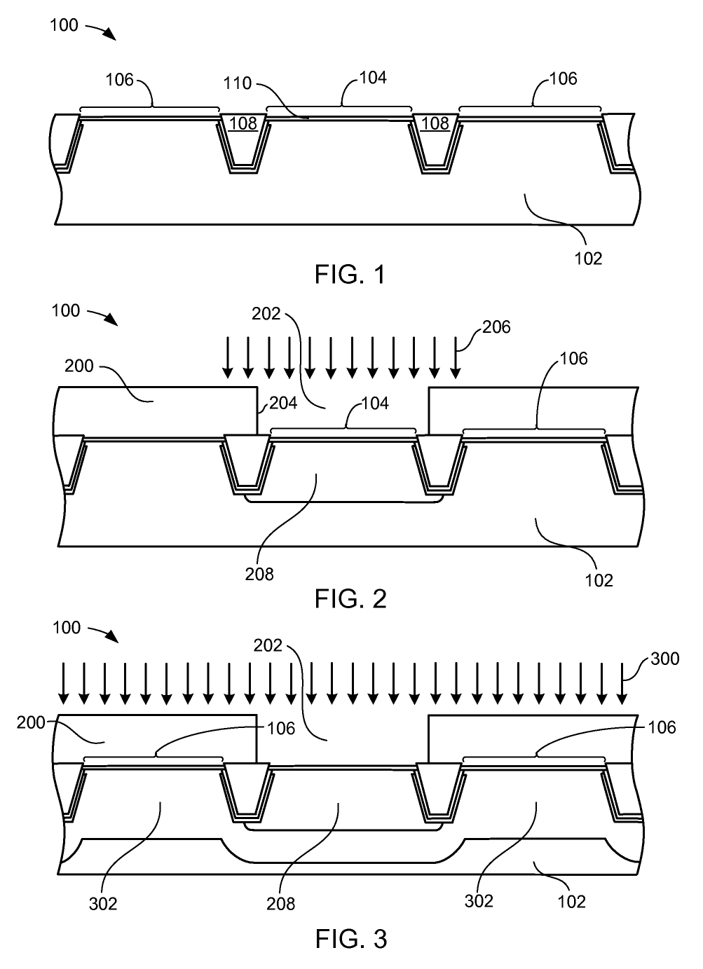

FIGS. 1-5, which follow, depict by way of example and not by limitation, an exemplary process flow for the formation of a substrate within an integrated circuit system and they are not to be construed as limiting. It is to be understood that a plurality of conventional processes that are well known within the art and not repeated herein, may precede or follow FIGS. 1-5. Moreover, it is to be understood that many modifications, additions, and/or omissions may be made to the below described process without departing from the scope or spirit of the claimed subject matter. For example, the below described process may include more, fewer, or other steps. Additionally, steps may be performed in any suitable order without departing from the scope of the present invention.

Moreover, it is to be appreciated that the integrated circuit system of the present disclosure may include any number of active devices (e.g., a multi-electrode device in which the current flowing between two specified electrodes is controlled or modulated by the voltage applied at a control electrode) and/or passive devices and their interconnections. Exemplary illustrations of the one or more active devices may include, without limitation, an n-channel field effect transistor (NFET), a p-channel field effect transistor (PFET), a complementary metal-oxide-silicon (CMOS) configuration, a single-gate transistor, a multi-gate transistor, a fin-FET, or an annular gate transistor. Exemplary illustrations of the one or more passive devices may include, without limitation, resistance devices with varying resistance values formed by strategically altering the process techniques. Furthermore, it is to be understood that one or more of the integrated circuit system could be prepared at one time on a medium, which could be separated into individual or multiple integrated circuit assemblies at a later stage of fabrication.

Furthermore, it is to be understood that the integrated circuit system manufactured by the embodiments described herein can be used within a multitude of electronic systems, such as processor components, memory components, logic components, digital components, analog components, mixed-signal components, power components, radio-frequency (RF) components (e.g., RF CMOS circuits), digital signal processor components, micro-electromechanical components, optical sensor components, and so forth, in numerous configurations and arrangements as may be needed.

Referring now to FIG. 1, therein is shown a partial cross-sectional view of an integrated circuit system 100 in an initial stage of manufacture in accordance with an embodiment of the present invention. In some embodiments, the integrated circuit system 100 may include a substrate 102, such as a two hundred (200) mm or three hundred (300) mm semiconductor wafer upon which any number of active and/or passive device structures and their interconnections could be formed. In such cases, a first region 104 and a second region 106 can be formed over, on and/or within the substrate 102 for the manufacture of active and/or passive device structures by conventional deposition, patterning, photolithography, and etching techniques known in the semiconductor processing industry.

In general, the substrate 102 may include any semiconducting material, such as, Si, SiC, SiGe, Si/SiGe, SiGeC, Ge, GaAs, InAs, InP, other III/V or II/VI compound semiconductors, as well as silicon-on-insulator configurations. Additionally, the substrate 102 may also include doped and undoped configurations, epitaxial layers, strained configurations, and one or more crystal orientations (e.g., <100>, <110>, and/or <111> orientations), which may be strategically employed to optimize carrier mobility within NFET and/or PFET devices. The substrate 102 may also include any material that becomes amorphous upon implantation.

In some embodiments, the substrate 102 may possess a thickness ranging from about one hundred (100) nanometers to about several hundred microns, for example.

However, the examples provided for the substrate 102 are not to be construed as limiting and the composition of the substrate 102 may include any surface, material, configuration, or thickness that physically and electrically enables the formation of active and/or passive device structures.

In some embodiments, the first region 104 and the second region 106 can be electrically isolated and/or separated by an isolation structure 108, such as a shallow trench isolation structure. For purposes of illustration, the isolation structure 108 may include a dielectric material such as silicon dioxide (“SiO₂”). However, it is to be understood that the isolation structure 108 is not limited to the preceding shallow trench isolation example, and may include any structure that helps to electrically isolate and/or separate the first region 104 from the second region 106, for example.

In other embodiments, the isolation structure 108 could be formed within the substrate 102 subsequent to forming the below described well regions.

In some embodiments, a material layer 110 can be optionally formed over the first region 104 and the second region 106. In some cases, the material layer 110 may include a grown or deposited oxide, a nitride layer, or a combination thereof By way of example, the thickness of the material layer 110 may depend upon its ability to act as a screening layer during implantation. In other embodiments, the material layer 110 may include one or more layers, wherein at least one of the layers includes an anti-reflective layer, such as an organic or an inorganic dielectric material that can suppress unintended energy/light reflection from the substrate 102 and/or the isolation structure 108. In such cases, the material layer 110 would be deposited over the entirety of the integrated circuit system 100. Generally, the anti-reflective layer may include one or more thin film layers of different material applied in a selected sequence.

It will be appreciated by those skilled in the art that the application of an anti-reflective layer can improve the sidewall angle (e.g., create a vertical sidewall) of a subsequently deposited and patterned opening within a masking layer, thereby helping to reduce implantation well proximity effects, threshold voltage variances, and active device parasitics, while improving inter-well isolation.

In yet other embodiments, the material layer 110 may also include a release layer or a primer formed between the substrate 102 and the anti-reflective layer and/or a subsequently deposited masking layer to facilitate removal of either.

Referring now to FIG. 2, therein is shown the structure of FIG. 1 after forming a mask layer 200. In some embodiments, the mask layer 200 can be a positive or negative photoresist that is patterned to form an opening 202 over the first region 104. In other embodiments, the mask layer 200 may include any material that can be patterned and used to block or permit the implantation of specific dopants within the substrate 102. Generally, the thickness of the mask layer 200 is between about 800 nanometers and about 1500 nanometers. However, larger or smaller thicknesses of the mask layer 200 may be appropriate depending on the design specifications of the integrated circuit system 100. Notably, in some embodiments, the mask layer 200 can be thick enough to prevent impurities from substantially penetrating through the mask layer 200 into the second region 106 during the implant of the first well 208.

It will be appreciated by those skilled in the art that the thickness range for the mask layer 200 is compatible with sub 65 nanometer technology where the lateral and vertical geometries of the integrated circuit system 100 are greatly reduced. The present inventors have discovered that by maintaining the mask layer 200 thickness below about 2000 nanometers that printability (e.g., the ability to transfer the image from mask/reticle to resist) of sub 65 nanometers features can be achieved with greater accuracy. However, it will be appreciated by those skilled in the art that below an empirically determined thickness, the mask layer 200 may not function as desired for a particular process (e.g., printability or blocking effects of the mask layer 200 may become compromised).

Moreover, the present inventors have discovered that by implanting in the presence of a relatively thin form of the mask layer 200 (e.g., the mask layer 200 thickness being substantially below about 2000 nanometers) that impurity scattering during implant can be substantially eliminated. It will be appreciated by those skilled in the art that a reduction in impurity scattering will help to substantially eliminate the well proximity effect and its adverse impact on threshold voltages and other electrical characteristics of active devices formed within the first region 104 and the second region 106.

Furthermore, it will be appreciated by those skilled in the art that the present embodiments can employ advanced patterning techniques when forming the opening 202 within the mask layer 200. The present inventors have discovered that by optimizing the process to form the opening 202 to minimize the taper or angle of a sidewall 204 that implantation well proximity effects, threshold voltage variances, and active device parasitics can be reduced because scattering of the implanted impurities can be decreased. In general, the present embodiments achieve the reduced scattering by substantially eliminating the taper or angle of the sidewall 204 (i.e., the sidewall 204 is formed to be substantially perpendicular with the conventional surface of the substrate 102).

After patterning the mask layer 200 to form the opening 202, a first dopant implant 206 can be performed to form a first well 208 via a single mask. In some embodiments, the first dopant implant 206 forms the first well 208 by a single implant step. However, in other embodiments, the first dopant implant 206 may include more than one implant step (e.g., to form a retrograde well) to form the first well 208.

Although the present embodiment depicts the mask layer 200 with only one of the opening 202, it is to be understood that the mask layer 200 may include more than one of the opening 202. Accordingly, the present embodiment may include any number (i.e., one or more) of the opening 202 within the mask layer 200 as required by the design specifications of the integrated circuit system 100.

The impurities or dopants used to form the first well 208 may include n-type or p-type, depending on the type of device to be subsequently formed within the first region 104 (e.g., p-type impurities for an NMOS device and n-type impurities for a PMOS device). Generally, the dopants used to form the first well 208 are of opposite conductivity type as compared to the dopants that would be used to form the source/drain of the subsequently formed device within the first region 104.

In some embodiments, the first region 104 is implanted with n-type impurities (i.e., the first dopant implant 206), such as phosphorus (P), arsenic (As), or antimony (Sb), to form an n-well. In general, the first dopant implant 206 may be performed at a high enough energy to form the first well 208 to a depth between approximately 500 nanometers and approximately 1500 nanometers and a concentration between approximately 1.0×10¹⁶ cm⁻³ and approximately 5.0×10¹⁸ cm⁻³, depending on the dopant used and the design specifications of the integrated circuit system 100. However, it is to be understood that the first well 208 can be formed with larger or smaller depths and/or concentrations depending upon the design specifications of the integrated circuit system 100.

Some exemplary implantation parameters for the first dopant implant 206 of the first well 208 may include phosphorus implanted at a dose between approximately 1×10¹³ ions/cm² and approximately 5×10¹³ ions/cm² at an energy between approximately 100 keV and approximately 500 keV. However, larger or smaller doses and energies may be employed depending upon the design specifications of the integrated circuit system 100. Alternatively, it is to be understood that arsenic or antimony may also be implanted at appropriate doses and energies to form the first well 208.

Additionally, it will be appreciated by those skilled in the art that the implant angle of the first dopant implant 206 used to from the first well 208 can be optimized to improve inter-well isolation between adjacent wells. In general, the angle of the implantation can vary between about zero (0) degrees and about ten (10) degrees relative to the conventional surface of the substrate 102, wherein zero (0) degrees is defined as being substantially perpendicular to the conventional surface of the substrate 102. It is to be understood that such angled or non-angled implants can be employed to minimize channeling and shadow effects. Additionally, in some embodiments, the substrate 102 may also be rotated during the implant to provide symmetrical forms of the first well 208.

Moreover, it will be appreciated by those skilled in the art that the parameters of the first dopant implant 206 may also be optimized to help control punchthrough current and short channel effects common to active devices subsequently formed within the first region 104.

Referring now to FIG. 3, therein is shown the structure of FIG. 2 during a second dopant implant 300.

Notably, the mask layer 200 and the opening 202 remain as they were during the first dopant implant 206, of FIG. 2, thereby eliminating mask overlay error and reducing the number of manufacturing steps. Accordingly, the first dopant implant 206 and the second dopant implant 300 forms the first well 208 and a second well 302, respectively, via a single mask. In some embodiments, the second dopant implant 300 forms the second well 302 by a single implant step (e.g., a single high energy p-type or n-type implant). In such cases, the present inventors have discovered that by performing only a single implantation step during the second dopant implant 300 that dopant scattering can be minimized and threshold voltage variances between adjacent structures can be improved (i.e., the present inventors have discovered that a single implant form of the second dopant implant 300 can reduce the occurrence of well proximity effects). However, in other embodiments, the second dopant implant 300 may include more than one implant step to form the second well 302.

The impurities or dopants used to form the second well 302 may include n-type or p-type, depending on the device subsequently to be formed within the second region 106 (e.g., p-type impurities for an NMOS device and n-type impurities for a PMOS device). Generally, the dopants used to form the second well 302 are of opposite conductivity type as compared to the dopants used to form the first well 208 and the dopants that would be used to form the source/drain of the subsequently formed device within the second region 106.

In some embodiments, the second region 106 is implanted with p-type impurities (i.e., the second dopant implant 300), such as boron (B) or difluoroborane (BF₂), to form a p-well. In general, the second dopant implant 300 may be performed at a high enough energy to form the second well 302 to a depth between approximately 500 nanometers and approximately 2000 nanometers and a concentration between approximately 1.0×10¹⁶ cm⁻³ and approximately 5.0×10¹⁸ cm⁻³, depending on the dopant used and the design specifications of the integrated circuit system 100. However, it is to be understood that the second well 302 can be formed with larger or smaller depths and/or concentrations depending upon the design specifications of the integrated circuit system 100.

Some exemplary implantation parameters for the second dopant implant 300 of the second well 302 may include boron implanted at a dose between approximately 1×10¹² ions/cm² and approximately 1×10¹³ ions/cm² at an energy greater than approximately 400 keV. In other embodiments, the second dopant implant 300 of the second well 302 may more specifically include boron implanted at an energy between approximately 400 keV and approximately 500 keV. However, larger or smaller doses and energies may be employed depending upon the design specifications of the integrated circuit system 100. Moreover, it is to be understood that the above parameters are not limiting and those skilled in the art will appreciate that additional parameters may also be employed/manipulated to effectuate the purpose of forming the second well 302 through the mask layer 200 and the opening 202.

Alternatively, it is to be understood that other p-type dopants may also be implanted at appropriate doses and energies to form the second well 302.

Moreover, it will be appreciated by those skilled in the art that the parameters of the second dopant implant 300 may also be optimized to help control punchthrough current and short channel effects common to active devices subsequently formed within the second region 106.

Notably, the profile and/or depth of the second well 302 within the substrate 102 can be strategically controlled for sub 65 nanometer device design by optimizing the thickness of the mask layer 200 (e.g., between about 800 nanometers and about 1500 nanometers) and the implant parameters of the second dopant implant 300. Moreover, the second dopant implant 300 may also possess sufficient energy and dose to envelop/overlap the first well 208. By enveloping and/or overlapping the first well 208 with the second well 302, the junction capacitance can be decreased, the switching speed of the integrated circuit system 100 can be enhanced, and n-well/n-well isolation can be improved due to the higher doping concentration within the second well 302 portion that overlaps the first well 208.

Additionally, since the present embodiments only use a single masking layer (i.e., the mask layer 200) during formation of the first well 208 and the second well 302, errors in masking layer offset have virtually been eliminated. Accordingly, it will be appreciated by those skilled in the art that the present embodiments improve inter-well isolation as masking layer offset errors are one of the main causes of leakage between adjacent wells.

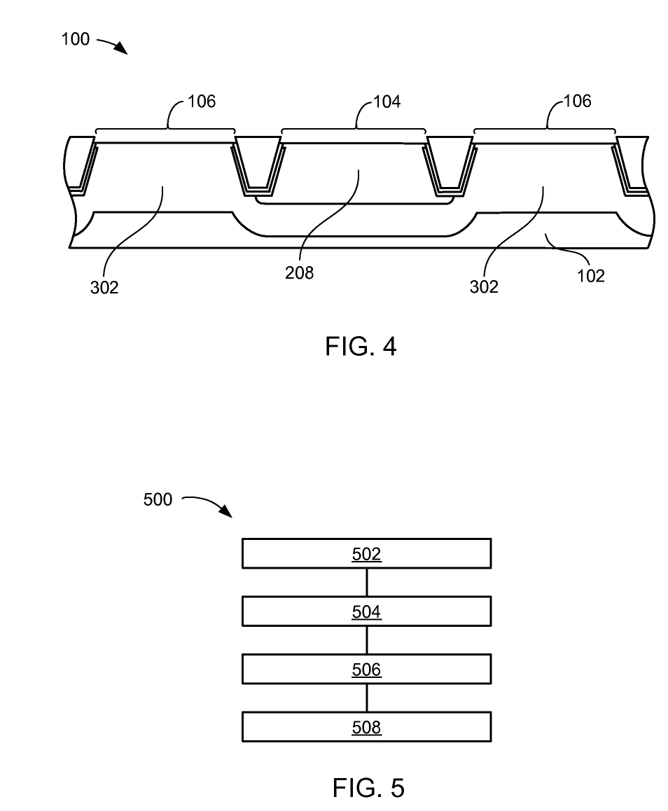

Referring now to FIG. 4, therein is shown the structure of FIG. 3 after removing the mask layer 200, of FIG. 3. The materials and techniques used to remove the mask layer 200 are well known within the art and not repeated herein. It will be appreciated by those skilled in the art that a clean step can be performed to remove surface contaminants, such as particles, mobile ionic contaminants, organics and native oxides from the exposed surfaces of the substrate 102 before forming subsequent process steps.

In some embodiments, subsequent to removing the mask layer 200, an anneal may be performed. It is to be understood that the anneal may include any thermal process that causes electrical activation of the dopants within the first well 208, the second well 302, channel regions and/or halo regions, for example. As exemplary illustrations, the anneal may include a rapid thermal anneal, a spike anneal, a millisecond anneal, a flash anneal, and/or a laser anneal.

Inasmuch as electronic devices will be subsequently formed within or over the first region 104 and the second region 106, a length and a width of each of the first region 104 and the second region 106 depends upon the number of such devices that will be formed therein or thereover. Since the number of such electronic devices could be as few as one or as many as thousands or more, each of the length and the width of the first region 104 and the second region 106 could generally be as small as an order of angstroms or as large as hundreds of microns, and will only be limited by the current processing technology node.

Moreover, it will be appreciated by those skilled in the art that after forming the first well 208 and the second well 302 that the integrated circuit system 100 is now ready for fabrication of electronic devices, which can be strategically designed and formed to implement the desired function of the integrated circuit system 100 (e.g., sub 65 nanometer CD active devices). By way of example, the electronic devices formed within the integrated circuit system 100 may include, but are not limited to, active components, passive components, processor components, memory components, logic components, digital components, analog components, mixed-signal components, power components, radio-frequency (RF) components (e.g., RF CMOS circuits), digital signal processor components, micro-electromechanical components, optical sensor components, and so forth, in numerous configurations and arrangements as may be needed.

Referring now to FIG. 5, therein is shown a flow chart of an integrated circuit system 500 for the integrated circuit system 100, in accordance with an embodiment of the present invention. The integrated circuit system 500 includes providing a substrate in a block 502; forming a mask layer over the substrate in a block 504; implanting a first well through an opening in the mask layer into the substrate in a block 506; and implanting a second well through the mask layer and the opening via a single implant into the substrate in a block 508.

It has been discovered that the present invention thus has numerous aspects. One such aspect is that the present invention reduces mask overlay error by employing only a single mask to form a first well and a second well.

Another aspect of the present invention is that it reduces costs and simplifies process operations by eliminating a mask step.

Another aspect of the present invention is that a single mask layer technique for well formations can produce similar n+/n-well and p+/p-well breakdown voltages as compared to previous double mask layer techniques.

Another aspect of the present invention is that mask layer thickness and single step well implant processes can be optimized to reduce well proximity effects.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit system of the present invention furnishes important and heretofore unknown and unavailable solutions, capabilities, and functional aspects for reducing costs and simplifying manufacturing operations. The resulting processes and configurations are straightforward, cost-effective, uncomplicated, highly versatile and effective, can be implemented by adapting known technologies, and are thus readily suited for efficiently and economically manufacturing integrated circuit package devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. A method for manufacturing an integrated circuit system comprising:
providing a substrate;
forming a mask layer over the substrate;
implanting a first well through an opening in the mask layer into the substrate; and
implanting a second well through the mask layer and the opening via a single implant into the substrate.

2. The method as claimed in claim 1 wherein:
forming the mask layer includes forming the mask layer with a thickness ranging from about 800 nanometers to about 1500 nanometers.

3. The method as claimed in claim 1 wherein:
implanting the first well includes implanting an n-type dopant.

4. The method as claimed in claim 1 wherein:
implanting the second well includes implanting a p-type dopant.

5. The method as claimed in claim 1 wherein:
implanting the second well includes implanting boron at about 400 keV or greater.

6. A method for manufacturing an integrated circuit system comprising:
providing a substrate including a first region, a second region, and an isolation structure;
forming a mask layer over the integrated circuit system with an opening over the first region;
implanting a first well through the opening; and
implanting a second well through the mask layer and the opening via a single implant.

7. The method as claimed in claim 6 wherein:
providing the substrate including the first region and the second region includes providing the first region formed adjacent the second region and separated by an isolation structure.

8. The method as claimed in claim 6 wherein:
forming the mask layer includes a thickness thereof that alters the well proximity effect.

9. The method as claimed in claim 6 wherein:
implanting the first well includes forming an n-type well.

10. The method as claimed in claim 6 wherein:
implanting the second well includes forming a p-type well.

11. A method for manufacturing an integrated circuit system comprising:
providing a substrate including a first region formed adjacent a second region with an isolation structure formed there between;
forming a mask layer over the integrated circuit system with an opening over the first region;
implanting a first well into the first region through the opening; and
implanting a second well into the second region through the mask layer and the opening via a single implant that envelopes the first well.

12. The method as claimed in claim 11 wherein:
forming the mask layer includes forming the mask layer with a thickness ranging from about 800 nanometers to about 1500 nanometers.

13. The method as claimed in claim 11 wherein:
implanting the first well includes implanting an n-type dopant.

14. The method as claimed in claim 11 wherein:
implanting the second well includes implanting a p-type dopant.

15. The method as claimed in claim 11 wherein:
implanting the second well includes implanting boron at about 400 keV or greater.

16. The method as claimed in claim 11 wherein:
implanting the second well includes implanting boron between about 400 keV and about 500 keV.

17. The method as claimed in claim 11 wherein:
forming the mask layer includes a thickness thereof that alters the well proximity effect.

18. The method as claimed in claim 11 wherein:
implanting the first well includes forming an n-type well.

19. The method as claimed in claim 11 wherein:
implanting the second well includes forming a p-type well.

20. The method as claimed in claim 11 wherein:
implanting the second well alters the junction capacitance of the integrated circuit system.
